(19) United States
(12) Patent Application Publication
(10) Pub. No.: US 2026/0091975 A1
(43) Pub. Date: Apr. 2, 2026

(54) MICRO-ELECTRO-MECHANICAL SYSTEM DEVICE AND MANUFACTURING METHODS OF MEMS DEVICE AND SEMICONDUCTOR DEVICE

(71) Applicant: Taiwan Semiconductor Manufacturing Company, Ltd., Hsinchu (TW)

(72) Inventors: Chin-Tai HUNG, Hsinchu (TW); Yu-Pei CHIANG, Hsinchu (TW); Shih-Wei HSU, Hsinchu (TW); Yuan-Te HUANG, Hsinchu (TW)

(73) Assignee: Taiwan Semiconductor Manufacturing Company, Ltd., Hsinchu (TW)

(21) Appl. No.: 18/904,816

(22) Filed: Oct. 2, 2024

(51) Int. Cl. B81C 1/00; B81B 3/00

(52) U.S. Cl. CPC B81C 1/00158; B81B 3/0024; B81B 2203/0127; B81B 2203/04; B81C 2201/0132

(57) ABSTRACT

A method for manufacturing a semiconductor device is provided, including the following steps. A metallized structure is formed on a membrane. A patterned photoresist layer is formed on the metallized structure, and the patterned photoresist layer has an opening. A first etching is performed to remove a portion of the metallization structure located below the opening to a first depth. A second etching is performed to remove the portion of the metallization structure located below the opening to a second depth that is greater than the first depth. A third etching is performed to remove the portion of the metallization structure located under the opening to a third depth that is greater than the second depth. The etchants used in the first and third etchings include chlorine, and the etchants used in the second etchings include chlorine and fluorine.

### BACKGROUND

Micro-electro-mechanical system (MEMS) is a technology that uses micro-mechanical and electromechanical components (e.g., devices or structures) on integrated chips. Using micro-fabrication techniques, MEMS devices can range from relatively simple structures with no moving components to complex electromechanical systems using a variety of moving components under the control of an integrated microelectronic controller. Devices or structures used in MEMS include micro-sensors, micro-actuators, microelectronics and microstructures. For example, MEMS devices can be used in a wide range of applications, including but not limited to motion sensors, pressure sensors, inertial sensors, micro-fluidic devices (e.g., valve, pump, nozzle control), optical devices, imaging devices (e.g., micro-machined ultrasonic transducers (MUT)), capacitive micro-machined ultrasonic transducer (CMUT) or similar.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B respectively illustrate a top view and a schematic cross-sectional view along line A-A of a semiconductor device according to an embodiment of the present disclosure.

FIG. 2 is a schematic diagram of the metallization structure disposed above the film in FIG. 1B.

FIGS. 3A to 3E are schematic diagrams of a method of manufacturing a semiconductor device according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

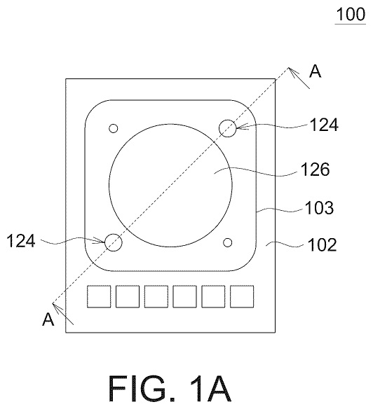

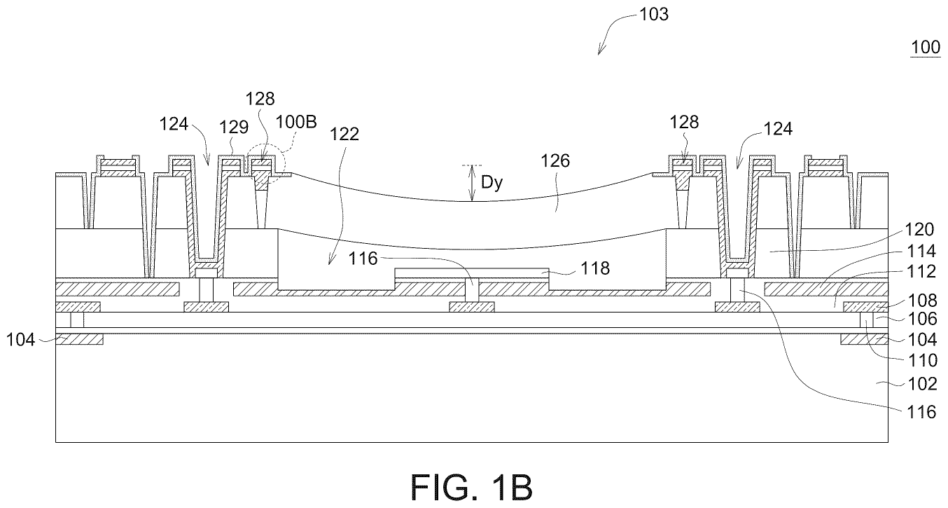

FIG. 1A and FIG. 1B respectively illustrate a top view and a schematic cross-sectional view along line A-A of a semiconductor device 100 according to an embodiment of the present disclosure. The semiconductor device 100 includes a substrate 102 and at least one pressure sensor unit 103 disposed on the substrate 102. Referring to FIG. IB, a substrate 102 is shown with one or more conductive components 104 disposed therein. According to one embodiment, the substrate 102 is an integrated circuit substrate, such as a complementary metal-oxide semiconductor (CMOS) substrate (also known as a CMOS substrate), and the one or more conductive components 104 are components of a CMOS circuit. In such embodiments, one or more conductive components 104 correspond to integrated circuit components (also referred to as IC components 104) disposed on or over the CMOS substrate 102. For example, suitable examples of such IC components may include, but are not limited to, active components (e.g., transistors), passive components (e.g., capacitors, inductors, resistors, and the like), or combinations thereof.

The semiconductor device 100 of FIG. 1B further shows a plurality of wires or conductive pads 108, which are disposed on a first dielectric layer 106 formed on the substrate 102. In some embodiments, multiple wires or conductive pads 108 may be implemented through Al-Cu pads. As depicted in FIG. 1B, the plurality of wires or conductive pads 108 are electrically coupled to corresponding conductive components 104 using one or more first vias 110. According to one embodiment, the first via 110 and the wire or conductive pad 108 are formed of the same conductive material (i.e., AlCu alloy). In other embodiments, conductive materials may include, for example, but are not limited to, metals (e.g., titanium, tungsten, silver, gold, aluminum, copper, or alloys thereof), metal nitrides, or any suitable combination thereof. In some embodiments, the wires or conductive pads 108 and the first via 110 may be patterned simultaneously or sequentially. The conductive components 104 and/or the wires or conductive pads 108 can be formed by, for example, chemical vapor deposition (CVD), physical vapor deposition (PVD), atomic layer deposition (ALD), electroless plating, electrochemical plating, sputtering, ion metal plasma, another deposition process, or any suitable combination thereof. In some embodiments, the wires or conductive pads 108 may be exposed through the first dielectric layer 106, such that the top surface of the wires or conductive pads 108 is not covered relative to the first dielectric layer 106. In other embodiments, the top surface in the wires or conductive pads 108 may be covered by the first dielectric layer 106.

Those skilled in the art will understand that the first dielectric layer 106 may be deposited from a suitable dielectric oxide. Suitable examples of first dielectric layer 106 may include, for example, but are not limited to, oxides (e.g., SiO2), nitrides (e.g., SiN), oxynitrides (e.g., SiO_{X}N_{Y}), some other dielectric material, or any suitable combination thereof. The first dielectric layer 106 may be deposited, for example, but not limited to, by CVD, PVD, ALD, some other deposition process, or any suitable combination thereof. According to one embodiment, those skilled in the art will understand that the image depicted in FIG. 1B corresponds to the redistribution layer formation and passivation process of the semiconductor device 100.

FIG. 1B illustrates the formation of a plurality of sensing vias 116 during the production process of the semiconductor device 100, according to one embodiment. As shown in FIG. 1B, a second dielectric layer 112 and a third dielectric layer 114 are respectively deposited on the semiconductor device 100. In some embodiments, the second dielectric layer 112 includes a suitable nitride material, such as, but not limited to, silicon nitride material. The third dielectric layer 114 may include, for example, but is not limited to, an oxide (e.g., SiO₂), a nitride (e.g., SiN), an oxynitride (e.g., SiO_{X}N_{Y}), some other dielectric material, or any suitable combination thereof. It should be understood that the first dielectric layer 106, the second dielectric layer 112 and the third dielectric layer 114 may comprise different dielectric materials, may be two layers the same with a remaining layer of a different dielectric material, or the like. The second dielectric layer 112 and the third dielectric layer 114 may be deposited by, for example, but not limited to, CVD, PVD, ALD, some other deposition process, or any suitable combination thereof. In different embodiments, those skilled in the art will understand that each of the second dielectric layer 112 and the third dielectric layer 114 may be deposited through different processes and may be deposited through different processing chambers or deposited using the same deposition process. More generally, at least a second dielectric layer 112 (also called a bottom dielectric layer) and a third dielectric layer 114 (also called a bottom dielectric layer) are deposited on the first dielectric layer 106 and the conductive wires or conductive pads 108.

As shown in FIG. 1B, a plurality of sensing vias 116 are formed in the second dielectric layer 112 and the third dielectric layer 114 (or more generally, at least one bottom dielectric layer 112, 114) and in contact with the wires or conductive pads 108. Suitable examples of such materials of sensing vias 116 may include, for example, but are not limited to metals (e.g., Al, Cu, AlCu, Ti, Ag, Au, W, or the like), metal nitrides (e.g., titanium nitride), some other conductive material, or any suitable combination thereof. It will be appreciated that sensing vias 116 may be deposited by, for example, but not limited to, CVD, PVD, ALD, electroless plating, electrochemical plating, sputtering, ionic metal plasma, another deposition process, or any suitable combination thereof.

In the exemplary embodiment, at least one bottom/sensing electrode 118 is the bottom electrode of pressure sensor unit 103. As shown in FIG. 1B, before dielectric film 120 is patterned (deposited and etched), bottom/sensing electrode 118 is patterned. The bottom/sensing electrode 118 is deposited over at least one bottom dielectric layer 112, 114 (hence the second and third dielectric layers 112, 114 are referred to as bottom dielectric layers). The bottom/sensing electrode 118 is patterned on the third dielectric layer 114 and in contact with the sensing via 116. According to various embodiments contemplated herein, the bottom/sensing electrode 118 may include, for example, but is not limited to, titanium (Ti) or other metals (e.g., Al, Cu, AlCu, Ag, Au, W, or the like), metal nitride (such as titanium nitride (TiN)), another conductive material, or any suitable combination thereof. The bottom/sensing electrode 118 may be deposited by, for example, but not limited to, CVD, PVD, ALD, electroless plating, electrochemical plating, sputtering, ionic metal plasma, another deposition process, or any suitable combination thereof.

In the exemplary embodiment, after the bottom/sensing electrode 118 on the semiconductor device 100 is patterned, a dielectric film 120 is deposited and patterned. The dielectric film 120 are referred to as the “top” dielectric layer because they are deposited on top of bottom/sensing electrode 118. According to one embodiment, the top dielectric film 120 completely covers the bottom/sensing electrode 118. Those skilled in the art will understand that the top dielectric film 120 may be deposited by, for example, but not limited to, CVD, PVD, ALD, some other deposition process, or any suitable combination thereof. The top dielectric film 120 can be subsequently etched to form a cavity 122, and the bottom/sensing electrode 118 is located in the cavity 122 surrounded by the top dielectric film 120. The etching process may be a dry etching process, a reactive ion etching (RIE) process, a wet etching process, some other etching process, or a combination of the above.

Next, a membrane 126 can be formed on the top dielectric film 120. The membrane 126 covers top dielectric film 120 to seal the cavity 122. According to some embodiments, the membrane 126 is configured to move or flap (e.g., flex, vibrate, etc.) in response to one or more stimulus (e.g., pressure, voltage, etc.). During operation of the pressure sensor unit 103, the membrane 126 flaps or vibrates in response to the stimulus described above. The membrane 126 is, for example, a silicon film. The thickness of the silicon membrane 126 should not be too small, preferably greater than 4.75 um. When the thickness of the silicon membrane 126 is too small, the membrane 126 may be easily flapping or vibrated, causing malfunction. In one embodiment, the deflection distance Dy from the center of the curved membrane 126 to the upper surface of the flat membrane 126 is less than 12.6 kÅ, for example.

In addition, the semiconductor device 100 includes a plurality of through holes 124 located above the conductive pads 108. These through holes 124 vertically penetrate the top dielectric film 120 and the surrounding portion of the membrane 126 to serve as dielectric windows for the conductive components. The formation of the through holes 124 can be accomplished through via etching (dry etching or wet etching). That is, through holes 124 may be created by forming a patterned mask layer (not shown) (e.g., positive/negative photoresist, hard mask, etc.) over membrane 126. Thereafter, an etching process is performed to remove the unmasked portions of the membrane 126 and subsequently the top dielectric film 120 to form the through holes 124.

In addition, the semiconductor device 100 also includes a metallization structure 128 located above the membrane 126. The metallization structure 128 extends into the through holes 124 and over the surrounding portion of the membrane 126 to serve as a seal metal layer of a vacuum chamber. The seal metal layer may include, for example, but is not limited to titanium (Ti) or other metals (such as Al, Cu, AlCu, Ag, Au, W, or the like), metal nitrides (such as titanium nitride (TiN)), another A conductive material, or any suitable combination thereof. The metallization structure 128 may be deposited by, for example, but not limited to, CVD, PVD, ALD, electroless plating, electrochemical plating, sputtering, ionic metal plasma, another deposition process, or any suitable combination thereof.

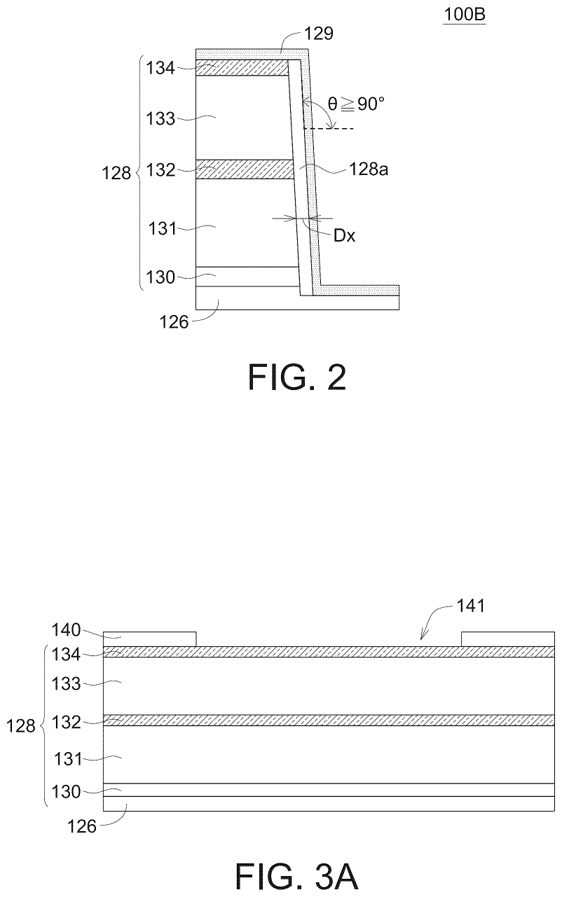

When forming the metallized structure 128 above the membrane 126, the etchant may not only remove the conductive material above the membrane 126, but may also over-etch the membrane 126, causing the thickness of the membrane 126 to be too small. Please refer to FIG. 2, a schematic diagram of the metallization structure 128 disposed above the membrane 126 at portion 100B in FIG. 1B is illustrated. The metallization structure 128 includes an adhesive layer 130, a first conductive layer 131, a first metal nitride layer 132, a second conductive layer 133 and a second metal nitride layer 134. The adhesive layer 130 is deposited on the membrane 126. The adhesive layer 130 may be, but is not limited to, titanium (Ti) or other metals. The first conductive layer 131 is deposited on the adhesive layer 130, and the first metal nitride layer 132 is deposited on the first conductive layer 131. The second conductive layer 133 is deposited on the first metal nitride layer 132, and the second metal nitride layer 134 is deposited on the second conductive layer 133. The first conductive layer 131 and the second conductive layer 133 are, for example, but not limited to AlCu alloy. The first metal nitride layer 132 and the second metal nitride layer 134 are, for example, but not limited to titanium nitride (TiN).

In addition, the upper surface and side walls of the metallized structure 128 and part of the upper surface of the membrane 126 can be covered with a protective layer 129 to protect the metallized structure 128. The protective layer 129 is, for example, silicon nitride or other insulating materials.

The etching process may use chlorine-containing gases (for example, Cl₂, CHCl₃, CCl₄ and/or BCl₃) and other suitable gases (for example, argon) as etchants to etch the adhesive layer 130, the conductive layer 131, the first metal nitride layer 132, the second conductive layer 133 and the second metal nitride layer 134. However, since the etchant containing chlorine gas has the same etching rate for the second conductive layer 133 and the first metal nitride layer 132, when the etchant containing chlorine gas etches the first metal nitride layer 132, sidewalls of the second conductive layer 133 will be etched back again by the etchant containing chlorine gas at the same time, so that the sidewalls of the second conductive layer 133 are recessed inward to generate defects. In view of above, the present disclosure proposes a method for manufacturing a semiconductor device, which improves the manufacturing of the metallization structure 128 above the membrane 126 to improve the yield of the process.

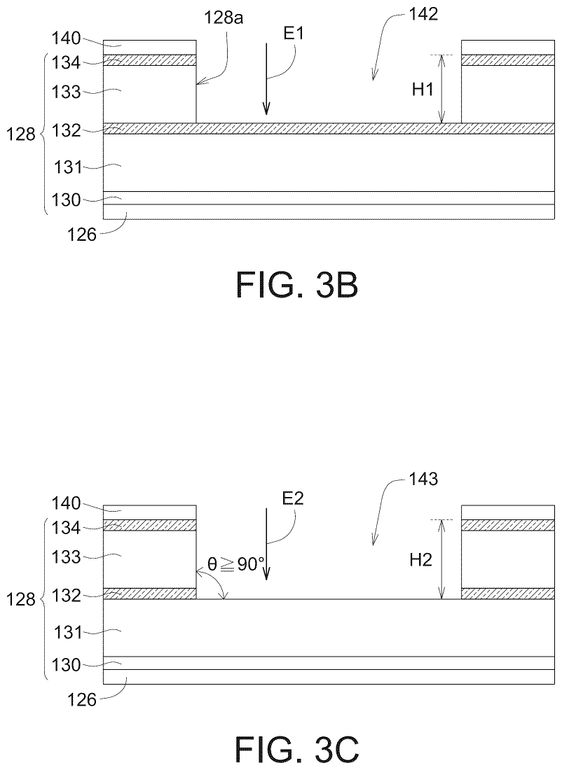

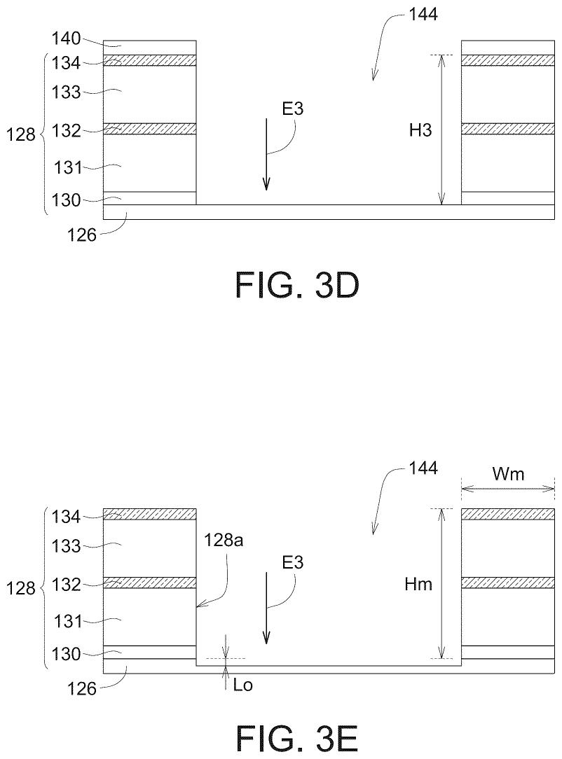

Referring to FIGS. 3A to 3E, schematic diagrams of a method of manufacturing a semiconductor device 100 according to an embodiment of the present disclosure are illustrated. The semiconductor device 100 is, for example, a MEMS device. The MEMS device includes a membrane 126 and a sensing electrode 118 (see FIG. 2). The method of manufacturing the semiconductor device 100 includes forming a metallization structure 128 on the membrane 126. The metallization structure 128 includes an adhesive layer 130, a first conductive layer 131, a first metal nitride layer 132, a second conductive layer 133 and a second metal nitride layer 134 in order from bottom to top. The first conductive layer 131 is deposited on the adhesive layer 130, and the first metal nitride layer 132 is deposited on the first conductive layer 131. The second conductive layer 133 is deposited on the first metal nitride layer 132, and the second metal nitride layer 134 is deposited on the second conductive layer 133. The thicknesses of the first conductive layer 131 and the second conductive layer 133 are, for example, greater than or equal to 15 kÅ, and the thicknesses of the first metal nitride layer 132 and the second metal nitride layer 134 are, for example, greater than or equal to 1 kÅ. The thicknesses of the first conductive layer 131 and the second conductive layer 133 may be greater than the thicknesses of the first metal nitride layer 132 and the second metal nitride layer 134.

As shown in FIG. 3A, a patterned photoresist layer 140 is formed on the metallized structure 128. The patterned photoresist layer 140 has an opening 141 to form a photoresist pattern with the opening 141 on the metallized structure 128. The patterned photoresist layer 140 may serve as an etch mask to etch the metallization structure 128 so as to transfer the photoresist pattern to the metallization structure 128. The metallization structure 128 may be etched using an anisotropic etching operation.

As shown in FIG. 3B, a first etching E1, such as an anisotropic etching, is performed to remove a portion of the metallization structure 128 located below the opening 141 to a first depth H1. The etchant used in the first etching E1 includes, for example, chlorine-containing gas (for example, Cl₂, CHCl₃, CCl₄, and/or BCl₃). After the etchant containing chlorine gas completely etches the uppermost second metal nitride layer 134, it continues etching the second conductive layer 133 of the next layer until the second conductive layer 133 is completely etched to form a first cavity 142. The depth of the first cavity 142 (i.e., the first depth H1) may be the sum of the thicknesses of the second conductive layer 133 and the second metal nitride layer 134.

Since the etchant containing chlorine gas has the same etching rate for the second conductive layer 133 and the second metal nitride layer 134, the second conductive layer 133 and the second metal nitride layer 134 have a flat sidewall 128a after etching. The sidewall 128a extends along the vertical direction. As shown in FIG. 2, the external angle θ between the sidewall 128a and the horizontal line (e.g., the surface of the membrane 126) is about 90 degrees or greater than 90 degrees (about 95 to 105 degrees).

As shown in FIG. 3C, a second etching E2 is performed, such as anisotropic etching, to remove the portion of the metallized structure 128 located below the opening 141 to a second depth H2, which is greater than the first depth H1. That is, the portion of the first metal nitride layer 132 located under the opening 141 is removed. The etchant used in the second etching E2 includes, for example, a mixture of chlorine-containing gas (e.g., Cl₂, CHCl₃, CCl₄, and/or BCl₃) and fluorine-containing gas (e.g., CF₄, SF₆, CH₂F₂, CHF₃, and/or C₂F₆). The percentage of fluorine-containing gas in the etchant may be greater than 23%, such as 30% or higher. In this embodiment, the etchant used to remove the first metal nitride layer 132 is different from the etchant used to remove the first conductive layer 131 and the second conductive layer 133 to avoid over-etching problem.

Taking the etchant containing chlorine and sulfur hexafluoride (SF₆) as an example, sulfur hexafluoride has a high etching selectivity for the first metal nitride layer 132 relative to the second conductive layer 133. Therefore, when sulfur hexafluoride selectively etches the first metal nitride layer 132, the etched sidewalls of the second conductive layer 133 will not continue to be etched to form defects. After the first metal nitride layer 132 is completely etched, a second cavity 143 is formed. The depth of the second cavity 143 (i.e., the second depth H2) may be the sum of the thicknesses of the first metal nitride layer 132, the second conductive layer 133, and the second metal nitride layer 134.

Since sulfur hexafluoride only etches the first metal nitride layer 132 formed of, for example, titanium nitride, it hardly etches the first conductive layer 131 and the second conductive layer 133 formed of, for example, AlCu alloy. Therefore, the first metal nitride layer 132 can be completely etched, and there is no problem of etching the first metal nitride layer 132 and etching the second conductive layer 133 at the same time.

As shown in FIG. 3D, a third etching E3, such as an anisotropic etching, is performed to remove the portion of the metallized structure 128 located below the opening 141 to a third depth H3. The third depth H3 is greater than the second depth H2. The etchant used in the third etching E3 includes, for example, chlorine-containing gas (for example, Cl₂, CHCl₃, CCl₄ and/or BCl₃). After the etchant containing chlorine gas completely etches the first metal nitride layer 132, it continues etching the adhesive layer 130 of next layer until the adhesive layer 130 is completely etched to form a third cavity 144. The depth of the third cavity 144 (i.e., the third depth H3) may be the sum of the thicknesses of the first conductive layer 131, the first metal nitride layer 132, the second conductive layer 133, and the second metal nitride layer 134, but the thickness of the adhesive layer 130 may also be included or ignored.

As shown in FIG. 3E, when performing the third etching E3, in addition to removing the first metal nitride layer 132, the membrane 126 will be further etched. Since the etchant containing chlorine gas can evenly etch the first metal nitride layer 132 and the membrane 126, the membrane 126 has a flat upper surface, thus improving the flatness of the membrane 126. At the same time, the silicon loss caused by etching can also be reduced. In one embodiment, the roughness of the surface of the membrane 126 can be maintained at less than 4.5 nm of Ra (average roughness) and less than 53 nm of Rmax (Maximum Roughness Depth). In addition, the silicon loss thickness Lo on the surface of the membrane 126 can be maintained at less than 1200 Å, which is approximately 0.5% to 5% of the thickness of the original membrane 126, to prevent the membrane 126 from being too thin and prone to flapping or vibration. In one embodiment, the thickness of the etched metallization structure 128 (i.e., the third depth H3) is at least 20 times the silicon loss thickness Lo.

In addition, the inside of the sidewall 128a of the metallized structure 128 contains components composed of atoms such as fluorine, oxygen, carbon, aluminum, silicon, chlorine, etc., and the components inside the sidewall 128a are analyzed through EDX (Energy Dispersive X-Ray) in the 30 nm range Dx (see FIG. 2), the atomic percentage of fluorine accounts for about 50-65% of the number of atoms in all components, and the atomic percentage of fluorine is about three times that of aluminum atoms. In addition, the ratio of the height Hm and the width Wm of the metallized structure 128 after etching is approximately greater than 1 or higher. Furthermore, due to the absence of defects caused by inward etching, the outer angle θ (i.e., exterior angle) of the sidewall 128a of the metallization structure 128 relative to the horizontal line (e.g., the surface of the membrane 126) is, for example, greater than or equal to 90 degrees.

The present disclosure is directed to methods for manufacturing a semiconductor device and a MEMS device, and the MEMS device includes a membrane and a metallized structure formed on the membrane. The first portion of the metallized structure in the top layer (such as AlCu alloy) is removed by an etchant containing chlorine gas, and then the second portion of the metallized structure in the middle layer (such as TiN) is removed by an etchant containing fluorine gas, but the top layer of the metallized structure is not removed by the etchant containing fluorine gas so as to avoid over-etching problem.

According to some embodiments of the present disclosure, a method for manufacturing a semiconductor device is provided, including the following steps. A metallized structure is formed on a membrane. A patterned photoresist layer is formed on the metallized structure, and the patterned photoresist layer has an opening. A first etching is performed to remove a portion of the metallization structure located below the opening to a first depth. A second etching is performed to remove the portion of the metallization structure located below the opening to a second depth that is greater than the first depth. A third etching is performed to remove the portion of the metallization structure located under the opening to a third depth that is greater than the second depth. The etchants used in the first and third etchings include chlorine, and the etchants used in the second etchings include chlorine and fluorine.

According to some embodiments of the present disclosure, a method for manufacturing a micro-electro-mechanical system (MEMS) device is provided. The method includes the following steps. A metallized structure is formed on a membrane of the MEMS device, and the metallized structure includes a first conductive layer, a first metal nitride layer, a second conductive layer and a second metal nitride layer in order from bottom to top. A patterned photoresist layer is formed on the metallized structure, and the patterned photoresist layer has an opening. A first etching is performed to remove a portion of the second metal nitride layer and a portion of the second conductive layer located below the opening to form a first cavity. A second etching is performed to remove a portion of the first metal nitride layer located below the opening to form a second cavity. A third etching is performed to remove a portion of the first conductive layer located below the opening to form a third cavity. An etchant used to remove the first metal nitride layer is different from an etchant used to remove the first conductive layer and the second conductive layer.

According to some embodiments of the present disclosure, a micro-electro-mechanical system (MEMS) device is provided, including a substrate, a sensing electrode, at least one dielectric film, a membrane and a metallization structure. The sensing electrode is disposed on the substrate. The dielectric film is disposed on the substrate, wherein the sensing electrode is located in a cavity surrounded by the dielectric film. The membrane covers the dielectric film to seal the cavity. A metallized structure is disposed on the membrane, and the metallized structure includes at least two conductive layers and at least two metal nitride layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a metallized structure on a membrane;
forming a patterned photoresist layer on the metallized structure, the patterned photoresist layer having an opening;
performing a first etching to remove a portion of the metallization structure located below the opening to a first depth;
performing a second etch to remove the portion of the metallization structure located below the opening to a second depth, the second depth being greater than the first depth; and
performing a third etching to remove the portion of the metallization structure located below the opening to a third depth, the third depth being greater than the second depth,
wherein an etchant used in the first and third etchings include chlorine, and an etchant used in the second etching include chlorine and fluorine.

2. The method of claim 1, wherein the metallization structure comprises a first conductive layer, a first metal nitride layer, a second conductive layer and a second metal nitride layer in order from bottom to top, the first metal nitride layer is located between the first conductive layer and the second conductive layer, wherein the method comprises:
performing the first etching to remove a portion of the second metal nitride layer and a portion of the second conductive layer located below the opening to form a first cavity;
performing the second etching to remove a portion of the first metal nitride layer located below the opening to form a second cavity; and
performing the third etching to remove a portion of the first conductive layer located below the opening to form a third cavity.

3. The method of claim 2, wherein a fluorine-containing gas of the etchant used in the second etching only reacts with the first metal nitride layer and does not react with the first conductive layer and the second conductive layer.

4. The method of claim 3, wherein the first metal nitride layer includes titanium nitride and the fluorine-containing gas includes sulfur hexafluoride.

5. The method of claim 3, wherein the first conductive layer and the second conductive layer comprise aluminum-copper alloy.

6. The method of claim 3, wherein a percentage of fluorine-containing gas in the etchant used for the second etching is greater than 23%.

7. The method of claim 2, wherein a chlorine-containing gas of the etchant used in the first and third etchings has an same etching rate for the first conductive layer, the second conductive layer and the second metal nitride layer.

8. The method of claim 7, wherein the chlorine-containing gas includes boron trichloride.

9. A method for manufacturing a micro-electro-mechanical system (MEMS) device, comprising:
forming a metallized structure on a membrane of the MEMS device, the metallized structure including a first conductive layer, a first metal nitride layer, a second conductive layer and a second metal nitride layer in order from bottom to top;
forming a patterned photoresist layer on the metallized structure, the patterned photoresist layer having an opening;
performing a first etching to remove a portion of the second metal nitride layer and a portion of the second conductive layer located below the opening to form a first cavity;
performing a second etching to remove a portion of the first metal nitride layer located below the opening to form a second cavity; and
performing a third etching to remove a portion of the first conductive layer located below the opening to form a third cavity,
wherein an etchant used to remove the first metal nitride layer is different from an etchant used to remove the first conductive layer and the second conductive layer.

10. The method of claim 9, wherein the etchant used in the first and third etchings includes chlorine, and the etchant used in the second etching includes chlorine and fluorine.

11. The method of claim 10, wherein a fluorine-containing gas of the etchant used in the second etching only reacts with the first metal nitride layer and does not react with the first conductive layer and the second conductive layer.

12. The method of claim 11, wherein the first metal nitride layer includes titanium nitride and the fluorine-containing gas includes sulfur hexafluoride.

13. The method of claim 11, wherein the first conductive layer and the second conductive layer comprise aluminum-copper alloy.

14. The method of claim 11, wherein a percentage of the fluorine-containing gas in the etchant used in the second etching is greater than 23%.

15. The method of claim 10, wherein the chlorine-containing gas of the etchant used in the first and third etchings has a same etching rate for the first conductive layer, the second conductive layer and the second metal nitride layer.

16. A micro-electro-mechanical system (MEMS) device, comprising:
a substrate;
a sensing electrode arranged on the substrate;
at least one dielectric film disposed on the substrate, wherein the sensing electrode is located in a cavity surrounded by the dielectric film;
a membrane covering the dielectric film to seal the cavity; and
a metallized structure disposed on the membrane, the metallized structure includes at least two conductive layers and at least two metal nitride layers.

17. The MEMS device of claim 16, wherein the metallized structure has a flat sidewall extending along a vertical direction, and the flat sidewall has an angle being greater than or equal to 90 degrees relative to a surface of the membrane.

18. The MEMS device of claim 17, wherein the flat sidewall contains fluorine, and an atomic percentage of fluorine in the flat sidewall is 50-65%.

19. The MEMS device of claim 16, wherein the membrane includes silicon, and a silicon loss thickness on the surface of the membrane is less than 1200 Å.

20. The MEMS device of claim 19, wherein the metallization structure has a thickness that is at least 20 times the silicon loss thickness.
